(19) United States
(12) Patent Application Publication
(10) Pub. No.: US 2019/0221279 A1
(43) Pub. Date: Jul. 18, 2019

(54) MEMORY SYSTEM AND OPERATING METHOD THEREOF

(71) Applicant: SK hynix Inc., Gyeonggi-do (KR)

(72) Inventor: Jong-Min LEE, Seoul (KR)

(21) Appl. No.: 16/043,745

(22) Filed: Jul. 24, 2018

(30) Foreign Application Priority Data
Jan. 12, 2018 (KR) 10-2018-0004389

(51) Int. Cl. G11C 29/08; G11C 29/50; G11C 29/52; G11C 16/10; G06F 12/02

(52) U.S. Cl. CPC G11C 29/08; G11C 29/50; G11C 2029/0401; G11C 16/10; G06F 12/0246; G11C 29/52

(57) ABSTRACT

A memory system includes a memory device including a plurality of memory blocks, a test mode unit suitable for determining a test mode, and a controller suitable for performing a fake write operation on the memory device corresponding to an operation result of the test mode unit.

### CROSS-REFERENCE TO RELATED APPLICATIONS

The present application claims priority under 35 U.S.C. § 119(a) to Korean Patent Application No. 10-2018-0004389, filed on Jan. 12, 2018, the disclosure of which is incorporated herein by reference in its entirety.

### BACKGROUND

### 1. Field

Various exemplary embodiments of the present invention relate to a memory system and, more particularly, to a memory system that is driven in a test mode, and an operating method thereof.

### 2. Description of the Related Art

The computer environment paradigm has changed to ubiquitous computing, which enables computing systems to be used at anytime and anywhere. As a result, use of portable electronic devices such as mobile phones, digital cameras, and laptop computers has rapidly increased. These portable electronic devices generally use a memory system having one or more memory devices for storing data. A memory system may be used as a main memory device or an auxiliary memory device of a portable electronic device.

Memory systems provide excellent stability, durability, high information access speed, and low power consumption since they have no moving parts. Examples of memory systems having such advantages include universal serial bus (USB) memory devices, memory cards having various interfaces, and solid state drives (SSD).

### SUMMARY

Various embodiments of the present invention are directed to a memory system capable of minimizing unnecessary operations in a test mode among a plurality of operations.

In accordance with an embodiment of the present invention, a memory system includes: a memory device including a plurality of memory blocks; a test mode unit suitable for determining a test mode; and a controller suitable for performing a fake write operation on the memory device corresponding to an operation result of the test mode unit.

The test mode unit may include: a fake write mode selection unit; and a fake write mode performing unit.

The fake write mode selection unit may select a fake write mode based on a test mode operation signal.

The test mode operation signal may be a signal that a host transmits to a memory system.

The test mode operation signal may be a signal that the controller transmits to the test mode unit.

The test mode operation signal may be a signal that a host transmits to a memory system along with a write command.

In the fake write mode, the fake write mode performing unit may request the controller to perform a fake write operation where a write operation is not actually performed on the memory device, and the controller may perform the fake write operation.

In the fake write mode, the fake write mode performing unit may request the controller to perform a fake write operation where a write operation is not actually performed on the memory device, and the controller may perform a fake garbage collection operation in the fake write mode.

In the fake write mode, the fake write mode performing unit may request the controller to perform a fake write operation where a write operation is not actually performed on the memory device, and the controller may perform a fake erase operation in the fake write mode.

In the fake write mode, the fake write mode performing unit may request the controller to perform a fake write operation where a write operation is not actually performed on the memory device, and the controller may perform a map update operation in the fake write mode.

In accordance with an embodiment of the present invention, an operating method of a memory system includes: determining a test mode; and performing a fake write operation on a memory device corresponding to a result of the determination.

The determining of the test mode may include: selecting a fake write mode; and performing the fake write mode.

The selecting of the fake write mode may be carried out to select the fake write mode based on a test mode operation signal.

The test mode operation signal may be a signal that a host transmits to a memory system.

The test mode operation signal may be a signal that a controller transmits to a test mode unit.

The test mode operation signal may be a signal that a host transmits to a memory system along with a write command.

The performing of the fake write mode may be carried out to request a controller to perform a fake write operation where a write operation is not actually performed on the memory device, and the controller may perform the fake write operation.

The performing of the fake write mode may be carried out to request a controller to perform a fake write operation where a write operation is not actually performed on the memory device, and the controller may perform a fake garbage collection operation in the fake write mode.

The performing of the fake write mode may be carried out to request a controller to perform a fake write operation where a write operation is not actually performed on the memory device, and the controller may perform a fake erase operation in the fake write mode.

The performing of the fake write mode may be carried out to request a controller to perform a fake write operation where a write operation is not actually performed on the memory device, and the controller may perform a map update operation in the fake write mode.

### BRIEF DESCRIPTION OF THE DRAWINGS

FIG. 1 is a block diagram illustrating a data processing system in accordance with an embodiment of the present invention.

FIG. 2 is a schematic diagram illustrating an exemplary configuration of a memory device employed in a memory system of FIG. 1.

FIG. 3 is a circuit diagram illustrating an exemplary configuration of a memory cell array of a memory block in the memory device shown in FIG. 1.

FIG. 4 is a block diagram illustrating an exemplary three-dimensional structure of the memory device shown in FIG.2.

FIG. 5 is a block diagram illustrating a memory system in accordance with an embodiment of the present invention.

FIG. 6 is a block diagram illustrating a configuration of a test mode unit in accordance with an embodiment of the present invention.

FIGS. 7 to 9 are flowcharts illustrating an operation of a memory system in accordance with embodiments of the present invention.

FIGS. 10 to 18 are diagrams schematically illustrating application examples of the data processing system, in accordance with various embodiments of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments. When an element is referred to as being connected or coupled to another element, it should be understood that the former can be directly connected or coupled to the latter, or electrically connected or coupled to the latter via an intervening element therebetween.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art, and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

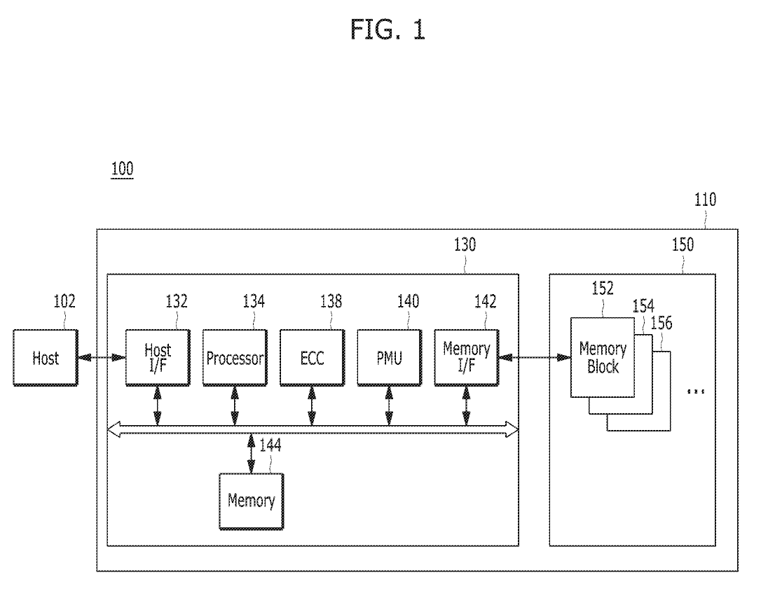

FIG. 1 is a block diagram illustrating a data processing system 100 including a memory system 110 in accordance with an embodiment of the present invention.

Referring to FIG. 1, the data processing system 100 may include a host 102 operatively coupled to the memory system 110.

The host 102 may include portable electronic devices such as a mobile phone, MP3 player and laptop computer or non-portable electronic devices such as a desktop computer, game machine, TV and projector.

The host 102 may include at least one OS (operating system), and the OS may manage and control overall functions and operations of the host 102, and provide an operation between the host 102 and a user using the data processing system 100 or the memory system 110. The OS may support functions and operations corresponding to the purpose and usage of a user. For example, the OS may be divided into a general OS and a mobile OS, depending on the mobility of the host 102. The general OS may be divided into a personal OS and an enterprise OS, depending on the environment of a user. For example, the personal OS configured to support a function of providing a service to general users may include Windows and Chrome, and the enterprise OS configured to secure and support high performance may include Windows server, Linux and Unix. Furthermore, the mobile OS configured to support a function of providing a mobile service to users and a power saving function of a system may include Android, iOS and Windows Mobile. The host 102 may include a plurality of OSs, and may execute an OS to perform an operation corresponding to a user's request on the memory system 110. Here, the host 102 may provide a plurality of commands corresponding to a user's request to the memory system 110, and thus the memory system 110 may perform certain operations corresponding to the plurality of commands, that is, corresponding to the user's request.

The memory system 110 may store data for the host 102 in response to a request of the host 102. Non-limited examples of the memory system 110 may include a solid state drive (SSD), a multi-media card (MMC), a secure digital (SD) card, a universal storage bus (USB) device, a universal flash storage (UFS) device, a compact flash (CF) card, a smart media card (SMC), a personal computer memory card international association (PCMCIA) card and a memory stick. The MMC may include an embedded MMC (eMMC), reduced size MMC (RS-MMC) and micro-MMC. The SD card may include a mini-SD card and micro-SD card.

The memory system 110 may include various types of storage devices. Non-limited examples of storage devices included in the memory system 110 may include volatile memory devices such as a dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM), and a flash memory.

The memory system 110 may include a memory device 150 and a controller 130. The memory device 150 may store data for the host 102, and the controller 130 may control data storage into the memory device 150.

The controller 130 and the memory device 150 may be integrated into a single semiconductor device, which may be included in the various types of memory systems as exemplified above. For example, the controller 130 and the memory device 150 may be integrated as one semiconductor device to constitute an SSD. When the memory system 110 is used as an SSD, the operating speed of the host 102 connected to the memory system 110 can be improved. In another example, the controller 130 and the memory device 150 may be integrated as one semiconductor device to constitute a memory card. For example, the controller 130 and the memory device 150 may constitute a memory card such as a PCMCIA (personal computer memory card international association) card, CF card, SMC (smart media card), memory stick, MMC including RS-MMC and micro-MMC, SD card including mini-SD, micro-SD and SDHC, or UFS device.

Non-limited application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device and may retain stored data even though power is not supplied. The memory device 150 may store data provided from the host 102 through a write operation, and provide data stored therein to the host 102 through a read operation. In an embodiment, the memory device 150 may include a plurality of memory dies (not shown), each memory may include a plurality of planes (not shown), each plane may include a plurality of memory blocks 152 to 156, each of the memory blocks 152 to 156 may include a plurality of pages, and each of the pages may include a plurality of memory cells coupled to a word line. In an embodiment, the memory device 150 may be a flash memory having a 3-dimensional (3D) stack structure.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, write, program and erase operations of the memory device 150.

More specifically, the controller 130 may include a host interface (I/F) unit 132, a processor 134, an error correction code (ECC) unit 138, a Power Management Unit (PMU) 140, a memory interface unit 142, and a memory 144 all operatively coupled via an internal bus.

The host interface unit 132 may process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (PATA), enhanced small disk interface (ESDI) and integrated drive electronics (IDE). The host interface unit 132 may be driven via a firmware, that is, a host interface layer (HIL) for exchanging data with the host 102.

Further, the ECC unit 138 may correct error bits of data to be processed by the memory device 150 and may include an ECC encoder and an ECC decoder. The ECC encoder may perform an error correction encoding on data to be programmed into the memory device 150 to generate data to which a parity bit is added. The data including the parity bit may be stored in the memory device 150. The ECC decoder may detect and correct an error contained in the data read from the memory device 150. In other words, the ECC unit 138 may perform an error correction decoding process to the data read from the memory device 150 through an ECC code used during an ECC encoding process. According to a result of the error correction decoding process, the ECC unit 138 may output a signal, for example, an error correction success/fail signal. When the number of error bits is more than a threshold value of correctable error bits, the ECC unit 138 may not correct the error bits, and may output an error correction fail signal.

The ECC unit 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM) and Block coded modulation (BCM). However, the ECC unit 138 is not limited thereto. The ECC unit 138 may include all circuits, modules, systems or devices for error correction.

The PMU 140 may provide and manage power of the controller 130.

The memory interface unit 142 may serve as a memory/storage interface for interfacing the controller 130 and the memory device 150 such that the controller 130 may control the memory device 150 in response to a request from the host 102. When the memory device 150 is a flash memory or specifically a NAND flash memory, the memory interface unit 142 may be NAND flash controller (NFC) and may generate a control signal for the memory device 150 and process data to be provided to the memory device 150 under the control of the processor 134. The memory interface unit 142 may work as an interface (e.g., a NAND flash interface) for processing a command and data between the controller 130 and the memory device 150. Specifically, the memory interface unit 142 may support data transfer between the controller 130 and the memory device 150. The memory interface unit 142 may be driven via a firmware, that is, a flash interface layer (FIL) for exchanging data with the memory device 150.

The memory 144 may serve as a working memory of the memory system 110 and the controller 130, and store data for driving the memory system 110 and the controller 130. The controller 130 may control the memory device 150 to perform read, program, and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be a volatile memory however, a non-volatile memory may be used instead. For example, the memory 144 may be a static random access memory (SRAM) or dynamic random access memory (DRAM). The memory 144 may be disposed within or out of the controller 130. FIG. 1 exemplifies the memory 144 disposed within the controller 130. In an embodiment, the memory 144 may be an external volatile memory having a memory interface transferring data between the memory 144 and the controller 130.

As described above, the memory 144 may include a program memory, a data memory, a write buffer/cache, a read buffer/cache, a data buffer/cache and a map buffer/cache to store data required to perform data write and read operations between the host 102 and the memory device 150 and data required for the controller 130 and the memory device 150 to perform these operations.

The processor 134 may control the overall operations of the memory system 110. The processor 134 may drive firmware to control the overall operations of the memory system 110. The firmware may be referred to as a flash translation layer (FTL).

For example, the controller 130 may perform an operation requested by the host 102 in the memory device 150 through the processor 134, which is implemented as a microprocessor, a CPU, or the like. In other words, the controller 130 may perform a command operation corresponding to a command received from the host 102. Herein, the controller 130 may perform a foreground operation as the command operation corresponding to the command received from the host 102. For example, the controller 130 may perform a program operation corresponding to a write command, a read operation corresponding to a read command, an erase operation corresponding to an erase command, and a parameter set operation corresponding to a set parameter command, or a set feature command as a set command.

Also, the controller 130 may perform a background operation on the memory device 150 through the processor 134, which is realized as a microprocessor or a CPU. Herein, the background operation performed on the memory device 150 may include an operation of copying and processing data stored in some memory blocks among the memory blocks 152 to 156 of the memory device 150 into other memory blocks, e.g., a garbage collection (GC) operation, an operation of performing swapping between the memory blocks 152 to 156 of the memory device 150 or between the data of the memory blocks 152 to 156, e.g., a wear-leveling (WL) operation, an operation of storing the map data stored in the controller 130 in the memory blocks 152 to 156 of the memory device 150, e.g., a map flush operation, or an operation of managing bad blocks of the memory device 150, e.g., a bad block management operation of detecting and processing bad blocks among the memory blocks 152 to 156 included in the memory device 150.

Also, in the memory system 110 in accordance with the embodiment of the present invention, the controller 130 may perform a plurality of command executions corresponding to a plurality of commands received from the host 102, e.g., a plurality of program operations corresponding to a plurality of write commands, a plurality of read operations corresponding to a plurality of read commands, and a plurality of erase operations corresponding to a plurality of erase commands, in the memory device 150. Also, the controller 130 may update meta-data, (particularly, map data) according to the command executions.

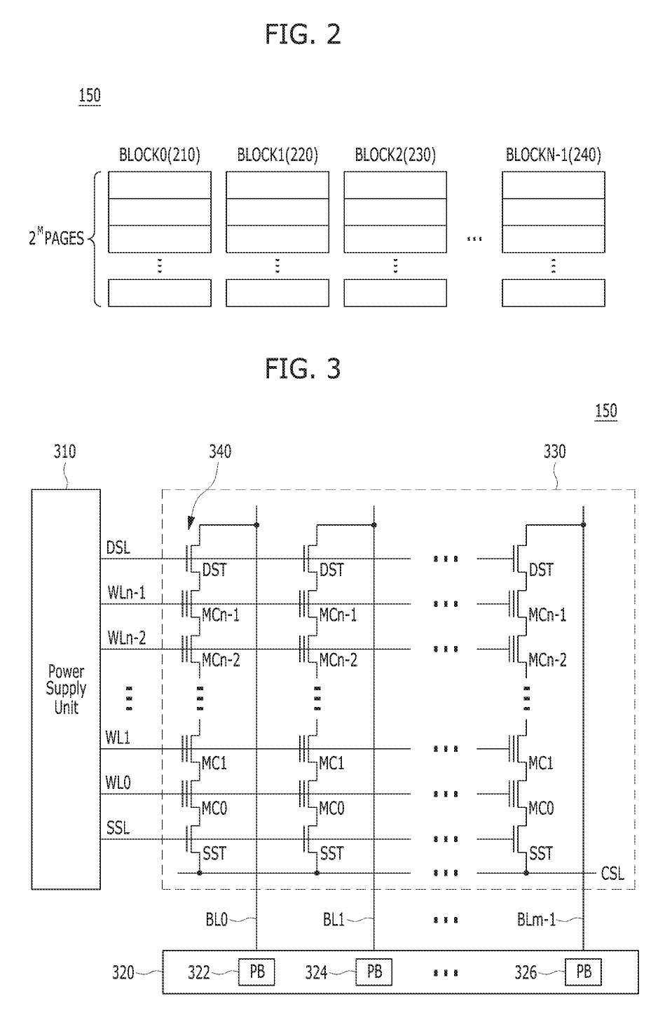

The processor 134 of the controller 130 may include a management unit (not illustrated) for performing a bad block management operation of the memory device 150. The management unit may perform a bad block management operation of checking a bad block, in which a program fail occurs due to the characteristic of a NAND flash memory during a program operation, among the plurality of memory blocks 152 to 156 included in the memory device 150. The management unit may write the program-failed data of the bad block to a new memory block. In the memory device 150 having a 3D stack structure, the bad block management operation may reduce the use efficiency of the memory device 150 and the reliability of the memory system 110. Thus, a bad block management operation performing with more reliability is needed. Hereafter, the memory device of the memory system in accordance with the embodiment of the present invention is described in detail with reference to FIGS. 2 to 4.

Referring to FIG. 2, the memory device 150 may include a plurality of memory blocks BLOCK0 to BLOCKN-1, where N is an integer greater than 1, and each of the blocks BLOCK0 to BLOCKN-1 may include a plurality of pages, for example, 2^{M} pages, where M is an integer greater than 0, the number of which may vary according to circuit design. Herein, although it is described that each of the memory blocks include 2^{M} pages, each of the memory blocks may include M pages as well. Each of the pages may include a plurality of memory cells that are coupled to a plurality of word lines WL.

Also, memory cells included in the respective memory blocks BLOCK0 to BLOCKN-1 may be one or more of a single level cell (SLC) memory block storing 1-bit data or a multi-level cell (MLC) memory block storing 2-bit data. Hence, the memory device 150 may include SLC memory blocks or MLC memory blocks, depending on the number of bits which can be expressed or stored in each of the memory cells in the memory blocks. The SLC memory blocks may include a plurality of pages which are embodied by memory cells each storing one-bit data and may generally have high data computing performance and high durability. The MLC memory blocks may include a plurality of pages which are embodied by memory cells each storing multi-bit data (for example, 2 or more bits), and may generally have a larger data storage space than the SLC memory block, that is, higher integration density. In another embodiment, the memory device 150 may include a plurality of triple level cell (TLC) memory blocks. In yet another embodiment, the memory device 150 may include a plurality of quadruple level cell (QLC) memory blocks. The TCL memory blocks may include a plurality of pages which are embodied by memory cells each capable of storing 3-bit data. The QLC memory blocks may include a plurality of pages which are embodied by memory cells each capable of storing 4-bit data.

Although the embodiment of the present invention exemplarily describes, for the sake of convenience in description, that the memory device 150 may be the nonvolatile memory, it may be implemented by any one of a phase change random access memory (PCRAM), a resistive random access memory (RRAM(ReRAM)), a ferroelectrics random access memory (FRAM), and a spin transfer torque magnetic random access memory (SST-RAM(STT-MRAM)).

The memory blocks 210, 220, 230 and 240 may store the data transferred from the host 102 through a program operation, and transfer data stored therein to the host 102 through a read operation.

Referring to FIG. 3, the memory block 330 may include a plurality of cell strings 340 coupled to a plurality of corresponding bit lines BL0 to BLm-1. The cell string 340 of each column may include one or more drain select transistors DST and one or more source select transistors SST. Between the drain and source select transistors DST and SST, a plurality of memory cells MC0 to MCn-1 may be coupled in series. In an embodiment, each of the memory cell transistors MC0 to MCn-1, where n is an integer greater than 1, may be embodied by an MLC capable of storing data information of a plurality of bits. Each of the cell strings 340 may be electrically coupled to a corresponding bit line among the plurality of bit lines BL0 to BLm-1, where m is an integer greater than 1. For example, as illustrated in FIG. 3, the first cell string is coupled to the first bit line BL0, and the last cell string is coupled to the last bit line BLm-1.

Although FIG. 3 illustrates NAND flash memory cells, the present disclosure is not limited thereto. It is noted that the memory cells may be NOR flash memory cells, or hybrid flash memory cells including two or more types of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply unit 310 which provides word line voltages including a program voltage, a read voltage, and a pass voltage to supply to the word lines according to an operation mode. The voltage generation operation of the voltage supply unit 310 may be controlled by a control circuit (not illustrated). Under the control of the control circuit, the voltage supply unit 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

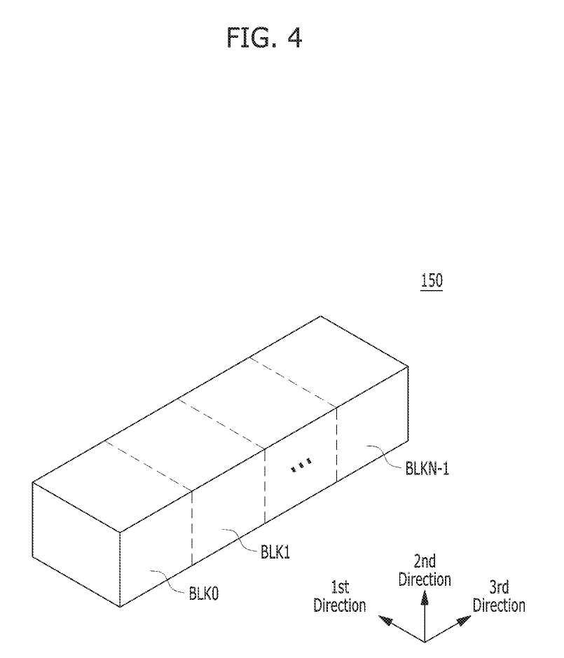

The memory device 150 may be embodied by a 2D or 3D memory device. Particularly, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1 each having a 3D structure (or vertical structure).

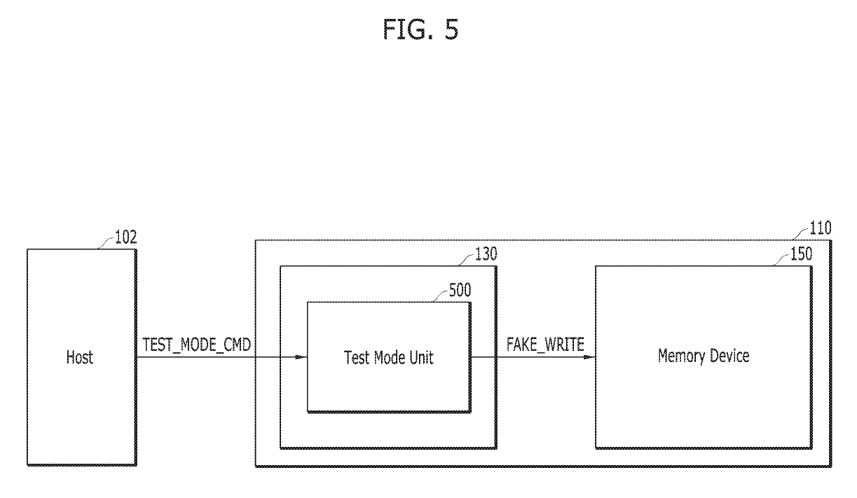

FIG. 5 is a block diagram illustrating a memory system 110 performing a fake write operation in a test mode in accordance with an embodiment of the present invention.

A write operation or a program operation of the memory system 110 may include an operation for transmitting write data from the host 102 to the memory system 110, an operation for transmitting a write command from the host 102 to the memory system 110, and an operation for writing write data to the memory system 110.

The operation for writing the write data to the memory system 110 may be the largest part of the write operation of the memory system 110.

In a circumstance of testing the memory system 110, the necessity of the operation for actually writing the write data may be relatively small.

That is, in the circumstance of testing the memory system 110, a fake write operation that does not actually write the write data may be performed, whereby the memory system 110 may be tested at a higher rate.

The memory system 110 in accordance with the embodiment of the present invention may include a test mode unit 500.

The test mode unit 500 may be included in the controller 130, the memory device 150 or the host 102. The test mode unit 500 may be implemented in hardware or software. That is, a location and a type that the test mode unit 500 is implemented in, may vary.

The test mode unit 500 may change the write operation of the memory system 110 and relevant operations to an operation corresponding to a test mode based on a test mode operation signal TEST_MODE_CMD.

The test mode operation signal TEST_MODE_CMD may be an individual signal that the host 102 transmits to the memory system 110.

Specifically, the host 102 may transmit the test mode operation signal TEST_MODE_CMD indicating the test mode to the memory system 110 to drive the memory system 110 in a test operation circumstance.

According to an embodiment of the present invention, the host 102 may transmit the test mode operation signal TEST_MODE_CMD simultaneously with the write command.

According to another embodiment of the present invention, the host 102 may directly control the test mode unit 500 through the controller 130, thereby changing a write mode to a fake write mode.

According to another embodiment of the present invention, the memory system 110 may set the fake write mode by itself through internal firmware of the memory system 110.

The operation corresponding to the test mode may be the fake write operation where the write operation is not performed on the memory device 150 in actuality.

Specifically, as described above, the read/write circuit 320 may receive data to be written to the cell array during the program operation, i.e., the write operation, from a buffer (not illustrated), and may drive bit lines based on inputted data.

Accordingly, in the test mode, the test mode unit 500 may not transmit write data to the read/write circuit 320 and may perform just a map update operation.

The operation corresponding to the test mode may be a fake erase operation where an erase operation is not performed on the memory device 150 in actuality.

During the fake erase operation, the test mode unit 500 may not perform the erase operation on the memory device 150 in actuality and may perform just the map update operation.

The operation corresponding to the test mode may be a fake garbage collection operation where a garbage collection operation is not performed on the memory device 150 in actuality.

During the fake garbage collection operation, the test mode unit 500 may not transmit/receive the write data to/from the memory device 150 and may perform just the map update operation.

The fake write operation, fake erase operation and fake garbage collection operation may not be performed at all in actuality and may be only some detailed operations performed among detailed operations included in each of the operations. The some detailed operations, as described above, may be the map update operation.

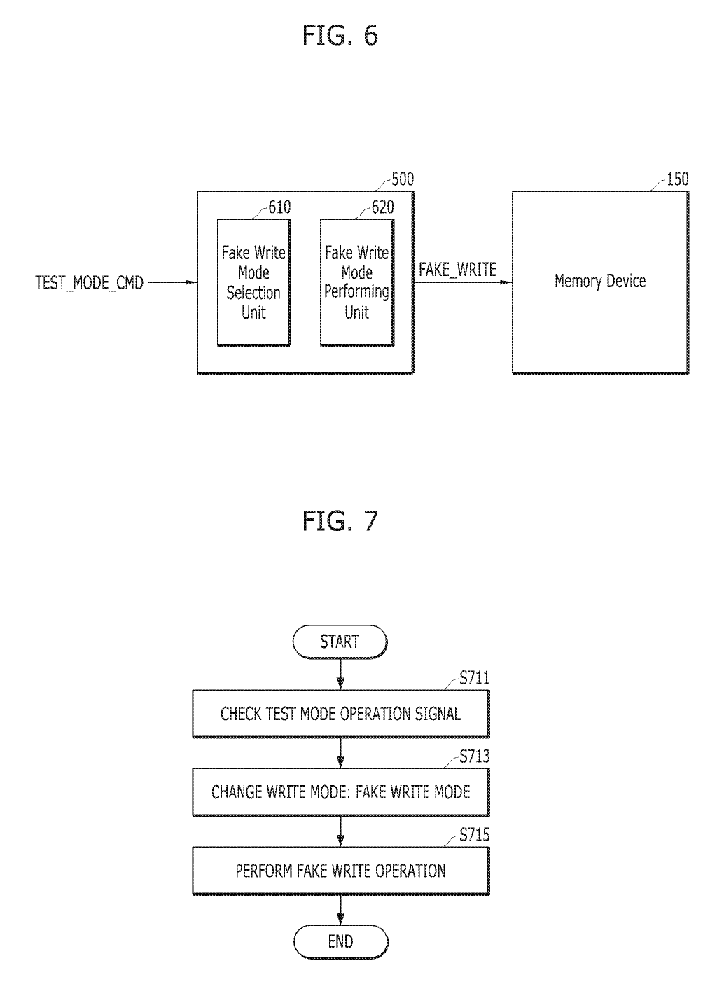

FIG. 6 is a block diagram illustrating a fake write mode selection unit 610 and a fake write mode performing unit 620 included in the test mode unit 500 shown in FIG. 5. The test mode unit 500, fake write mode selection unit 610, and the fake write mode performing unit 620 may include all circuits, systems, firmware and devices necessary for their respective operations and functions.

The fake write mode selection unit 610 may select the fake write mode corresponding to the test mode operation signal TEST_MODE_CMD.

The test mode operation signal TEST_MODE_CMD may be an individual signal that the host 102 transmits to the memory system 110.

Specifically, the host 102 may transmit the test mode operation signal TEST_MODE_CMD indicating the test mode to the memory system 110 to drive the memory system 110 in a test operation circumstance.

The fake write mode selection unit 610 may receive the test mode operation signal TEST_MODE_CMD and set the write mode of the memory system 110 to the fake write mode.

According to an embodiment of the present invention, the test mode operation signal TEST_MODE_CMD may be a signal that the controller 130 transmits to the test mode unit 500.

In other words, the controller 130 may transmit the test mode operation signal TEST_MODE_CMD indicating the test mode to the fake write mode selection unit 610 to drive the memory system 110 in the test operation circumstance.

The fake write mode selection unit 610 may receive the test mode operation signal TEST_MODE_CMD and set the write mode of the memory system 110 to the fake write mode.

The test mode operation signal TEST_MODE_CMD may be a signal that the host 102 transmits to the memory system 110 together with the write command.

Specifically, the host 102 may transmit the test mode operation signal TEST_MODE_CMD indicating the test mode to the memory system 110 together with the write command to drive the memory system 110 in the test operation circumstance.

The fake write mode selection unit 610 may receive the test mode operation signal TEST_MODE_CMD and set the write mode of the memory system 110 to the fake write mode.

The fake write mode performing unit 620 may directly perform an operation corresponding to the fake write mode or may request the controller 130 to perform the operation corresponding to the fake write mode based on an operation result of the fake write mode selection unit 610.

The controller 130 may not perform an actual write operation in the fake write mode based on a fake write mode set result of the fake write mode selection unit 610.

Specifically, the controller 130 may not perform an operation of writing the write data to a memory block of the memory device 150 among operations involved in the write operation.

In other words, the controller 130 may perform remaining operations except for the operation of writing the write data to the memory block of the memory device 150. As described above, the controller 130 may perform the map update operation through the test mode unit 500. Thus, the write operation that minimizes latency and is optimized for the test operation circumstance may be performed.

The controller 130 may not perform an actual garbage collection operation in the fake write mode.

Specifically, the controller 130 may not perform an operation of writing the write data to a memory block of the memory device 150 among operations involved in the garbage collection operation.

In other words, the controller 130 may perform remaining operations except for the operation of writing the write data to the memory block of the memory device 150. As described above, the controller 130 may perform the map update operation through the test mode unit 500.

Thus, the garbage collection operation that minimizes latency and is optimized for the test operation circumstance may be performed.

The controller 130 may not perform an actual erase collection operation in the fake write mode.

This is because an operation of writing the write data to a memory block of the memory device 150 is not performed in the fake write mode. Since there is no need to erase data that is not written, it is not necessary to actually perform the erase operation.

In other words, the controller 130 may perform remaining operations except for an operation of actually erasing the write data. Thus, the write and erase operations that minimize latency and are optimized for the test operation circumstance may be performed.

FIG. 7 is a flowchart illustrating an operation of the memory system 110 in the fake write mode in accordance with an embodiment of the present invention.

In step S711, the test mode unit 500 may receive a test mode operation signal.

Specifically, the host 102 may transmit the test mode operation signal indicating the test mode to the memory system 110 to drive the memory system 110 in a test operation circumstance.

In addition, the controller 130 may transmit the test mode operation signal indicating the test mode to the fake write mode selection unit 610 to drive the memory system 110 in the test operation circumstance.

In addition, the host 102 may transmit the test mode operation signal indicating the test mode to the memory system 110 together with a write command to drive the memory system 110 in the test operation circumstance.

In step S713, the fake write mode selection unit 610 may receive the test mode operation signal and set the write mode of the memory system 110 to the fake write mode.

In step S715, the fake write mode performing unit 620 may directly perform an operation corresponding to the fake write mode or may request the controller 130 to perform the operation corresponding to the fake write mode based on an operation result of the fake write mode selection unit 610.

The controller 130 may not perform an actual write operation in the fake write mode.

Specifically, the controller 130 may not perform an operation of writing the write data to a memory block of the memory device 150 among operations involved in the write operation.

In other words, the controller 130 may perform remaining operations except for the operation of writing the write data to the memory block of the memory device 150. Thus, the write operation that minimizes latency and is optimized for the test operation circumstance may be performed.

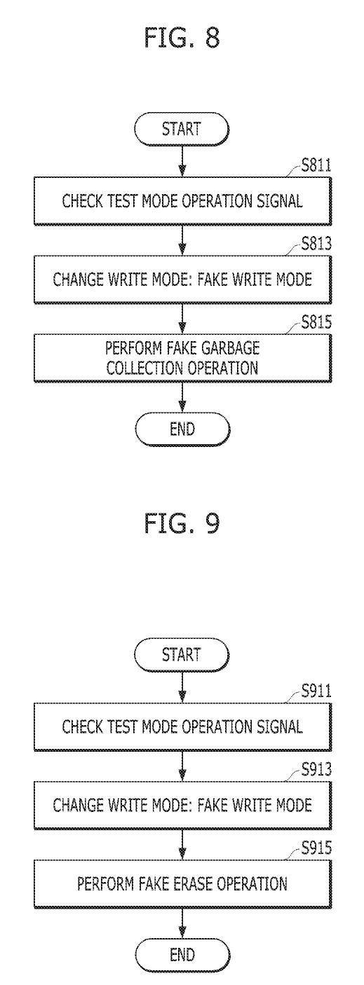

FIG. 8 is a flowchart illustrating an operation of the memory system 110 in the fake write mode in accordance with an embodiment of the present invention.

In step S811, the test mode unit 500 may receive a test mode operation signal.

Specifically, the host 102 may transmit the test mode operation signal indicating the test mode to the memory system 110 to drive the memory system 110 in a test operation circumstance.

In addition, the controller 130 may transmit the test mode operation signal indicating the test mode to the fake write mode selection unit 610 to drive the memory system 110 in the test operation circumstance.

In addition, the host 102 may transmit the test mode operation signal indicating the test mode to the memory system 110 together with a write command to drive the memory system 110 in the test operation circumstance.

In step S813, the fake write mode selection unit 610 may receive the test mode operation signal and set the write mode of the memory system 110 to the fake write mode.

In step S815, the fake write mode performing unit 620 may directly perform an operation corresponding to the fake write mode or may request the controller 130 to perform the operation corresponding to the fake write mode based on an operation result of the fake write mode selection unit 610.

The controller 130 may not perform an actual garbage collection operation in the fake write mode.

Specifically, the controller 130 may not perform an operation of writing the write data to a memory block of the memory device 150 among operations involved in the garbage collection operation.

In other words, the controller 130 may perform remaining operations except for the operation of writing the write data to the memory block of the memory device 150. Thus, the garbage collection operation that minimizes latency and is optimized for the test operation circumstance may be performed.

FIG. 9 is a flowchart illustrating an operation of the memory system 110 in the fake write mode in accordance with an embodiment of the present invention.

In step S911, the test mode unit 500 may receive a test mode operation signal.

Specifically, the host 102 may transmit the test mode operation signal indicating the test mode to the memory system 110 to drive the memory system 110 in a test operation circumstance.

In addition, the controller 130 may transmit the test mode operation signal indicating the test mode to the fake write mode selection unit 610 to drive the memory system 110 in the test operation circumstance.

In addition, the host 102 may transmit the test mode operation signal indicating the test mode to the memory system 110 together with a write command to drive the memory system 110 in the test operation circumstance.

In step S913, the fake write mode selection unit 610 may receive the test mode operation signal and set the write mode of the memory system 110 to the fake write mode.

In step S915, the fake write mode performing unit 620 may directly perform an operation corresponding to the fake write mode or may request the controller 130 to perform the operation corresponding to the fake write mode based on an operation result of the fake write mode selection unit 610.

The controller 130 may not perform an actual erase operation in the fake write mode.

This is because an operation of writing the write data to a memory block of the memory device 150 is not performed in the fake write mode. Since there is no need to erase data that is not written, it is not necessary to actually perform the erase operation.

In other words, the controller 130 may perform remaining operations except for an operation of actually erasing the write data. Thus, the write and erase operations that minimize latency and are optimized for the test operation circumstance may be performed.

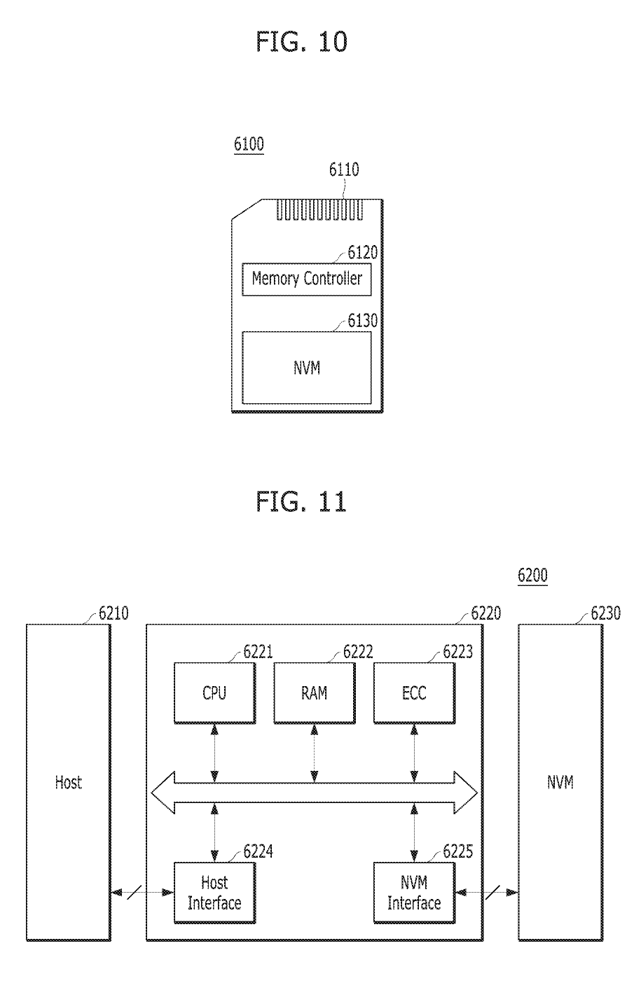

Hereafter, various data processing systems and electronic devices to which the memory system 110 including the memory device 150 and the controller 130, as described above with reference to FIGS. 1 to 9, in accordance with the embodiment of the present disclosure will be described in detail with reference to FIGS. 10 to 18.

FIG. 10 is a diagram schematically illustrating another example of the data processing system including the memory system in accordance with the present embodiment. FIG. 10 schematically illustrates a memory card system to which the memory system in accordance with the present embodiment is applied.

Referring to FIG. 10, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIG. 1, and the memory device 6130 may correspond to the memory device 150 of the memory system 110 described with reference to FIG. 1.

Thus, the memory controller 6120 may include a RAM, a processing unit, a host interface, a memory interface and an error correction unit.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with the present embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM).

The memory controller 6120 and the memory device 6130 may be integrated into a single semiconductor device. For example, the memory controller 6120 and the memory device 6130 may construct a solid-state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 11 is a diagram schematically illustrating another example of the data processing system including the memory system in accordance with the present embodiment.

Referring to FIG. 11, the data processing system 6200 may include a memory device 6230 having one or more nonvolatile memories and a memory controller 6220 for controlling the memory device 6230. The data processing system 6200 illustrated in FIG. 11 may serve as a storage medium such as a memory card (CF, SD, micro-SD or the like) or USB device, as described with reference to FIG. 1. The memory device 6230 may correspond to the memory device 150 in the memory system 110 illustrated in FIG. 1, and the memory controller 6220 may correspond to the controller 130 in the memory system 110 illustrated in FIG. 1.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and may be used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with the present embodiment may be applied to wired/wireless electronic devices or particularly a mobile electronic device.

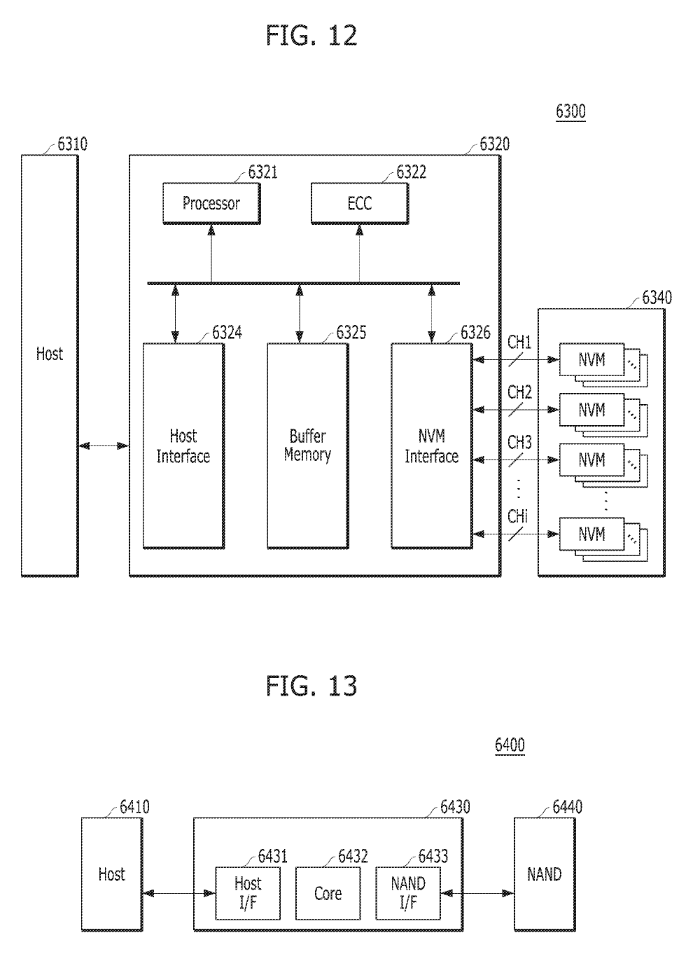

FIG. 12 is a diagram schematically illustrating another example of the data processing system including the memory system in accordance with the present embodiment. FIG. 12 schematically illustrates an SSD to which the memory system in accordance with the present embodiment is applied.

Referring to FIG. 12, the SSD 6300 may include a controller 6320 and a memory device 6340 including a plurality of nonvolatile memories. The controller 6320 may correspond to the controller 130 in the memory system 110 of FIG. 1, and the memory device 6340 may correspond to the memory device 150 in the memory system of FIG. 1.

More specifically, the controller 6320 may be connected to the memory device 6340 through a plurality of channels CH1 to Chi, where I is an integer greater than 1. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 12 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIG. 1 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 13 is a diagram schematically illustrating another example of the data processing system including the memory system in accordance with the present embodiment. FIG. 13 schematically illustrates an embedded Multi-Media Card (eMMC) to which the memory system in accordance with the present embodiment is applied.

Referring to FIG. 13, the eMMC 6400 may include a controller 6430 and a memory device 6440 embodied by one or more NAND flash memories. The controller 6430 may correspond to the controller 130 in the memory system 110 of FIG. 1, and the memory device 6440 may correspond to the memory device 150 in the memory system 110 of FIG. 1.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

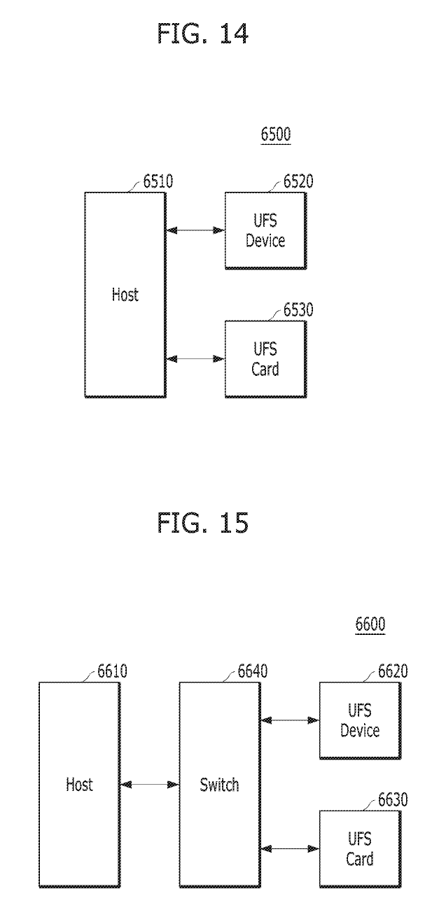

FIGS. 14 to 17 are diagrams schematically illustrating other examples of the data processing system including the memory system in accordance with the present embodiment. FIGS. 14 to 17 schematically illustrate UFS (Universal Flash Storage) systems to which the memory system in accordance with the present embodiment is applied.

Referring to FIGS. 14 to 17, the UFS systems 6500, 6600, 6700 and 6800 may UFS devices 6520, 6620, 6720 and 6820 and UFS cards 6530, 6630, 6730 and 6830, respectively. Hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIG. 1. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 11 to 13, and the UFS cards 6530, 6630, 6730 and 6830 may be embodied in the form of the memory card system 6100 described with reference to FIG. 10.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 14, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. At this time, the UFS device 6520 and the UFS card 6530 may communicate with each other through link layer switching at the UniPro of the host 6510. In the present embodiment, the configuration in which one UFS device 6520 and one UFS card 6530 are connected to the host 6510 has been exemplified for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 15, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 has been exemplified for convenience of description. However, a plurality of UFS devices and UFS cards may be connected in parallel or in the form of a star to the switching module 6640, and a plurality of UFS cards may be connected in series or in the form of a chain to the UFS device 6620.

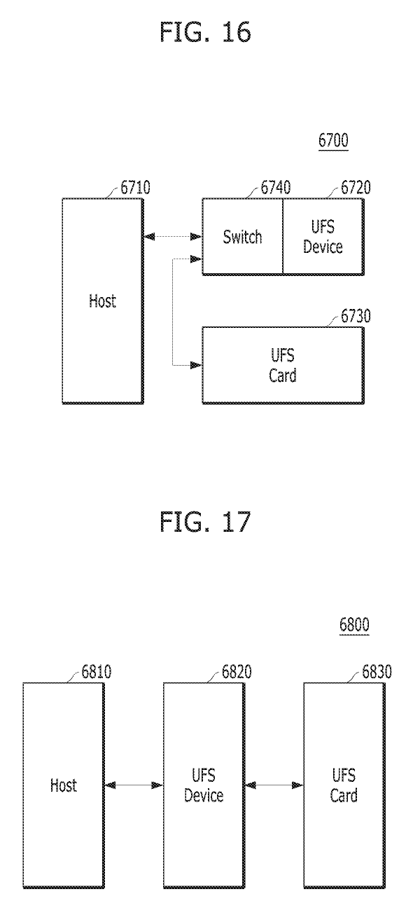

In the UFS system 6700 illustrated in FIG. 16, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. At this time, the UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 has been exemplified for convenience of description. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 17, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. At this time, the host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 has been exemplified for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

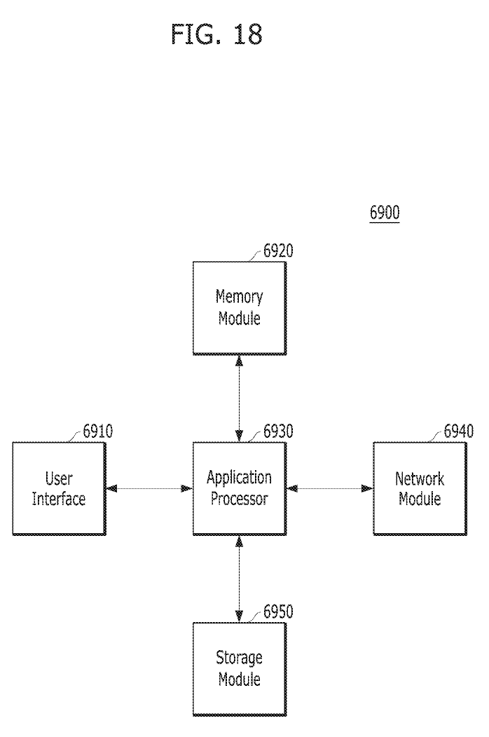

FIG. 18 is a diagram schematically illustrating another example of the data processing system including the memory system in accordance with an embodiment of the present invention. FIG. 18 is a diagram schematically illustrating a user system to which the memory system in accordance with the present embodiment is applied.

Referring to FIG. 18, the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices or particularly mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIG. 1. Furthermore, the storage module 6950 may be embodied as an SSD, eMMC and UFS as described above with reference to FIGS. 12 to 17.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIG. 1 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

In accordance with embodiments of the present invention, an unnecessary write operation and relevant operations may be minimized in a test mode, whereby an efficient test mode circumstance may be established.

While the present invention has been described with respect to specific embodiments, it will be apparent to those skilled in the art that various changes and modifications may be made without departing from the spirit and scope of the invention as defined in the following claims.

What is claimed is:

1. A memory system, comprising:
a memory device including a plurality of memory blocks;
a test mode unit suitable for determining a test mode; and
a controller suitable for performing a fake write operation on the memory device corresponding to an operation result of the test mode unit.

2. The memory system of claim 1, wherein the test mode unit includes:
a fake write mode selection unit; and
a fake write mode performing unit.

3. The memory system of claim 2, wherein the fake write mode selection unit selects a fake write mode based on a test mode operation signal.

4. The memory system of claim 3, wherein the test mode operation signal is a signal that a host transmits to a memory system.

5. The memory system of claim 3, wherein the test mode operation signal is a signal that the controller transmits to the test mode unit.

6. The memory system of claim 3, wherein the test mode operation signal is a signal that a host transmits to a memory system along with a write command.

7. The memory system of claim 3, wherein in the fake write mode, the fake write mode performing unit requests the controller to perform a fake write operation where a write operation is not actually performed on the memory device, and the controller performs the fake write operation.

8. The memory system of claim 3, wherein in the fake write mode, the fake write mode performing unit requests the controller to perform a fake write operation where a write operation is not actually performed on the memory device, and the controller performs a fake garbage collection operation in the fake write mode.

9. The memory system of claim 3, wherein in the fake write mode, the fake write mode performing unit requests the controller to perform a fake write operation where a write operation is not actually performed on the memory device, and the controller performs a fake erase operation in the fake write mode.

10. The memory system of claim 3, wherein in the fake write mode, the fake write mode performing unit requests the controller to perform a fake write operation where a write operation is not actually performed on the memory device, and the controller performs a map update operation in the fake write mode.

11. An operating method of a memory system, comprising:
determining a test mode; and
performing a fake write operation on a memory device corresponding to a result of the determination.

12. The operating method of claim 11, wherein the determining of the test mode includes:
selecting a fake write mode; and
performing the fake write mode.

13. The operating method of claim 12, wherein the selecting of the fake write mode is carried out to select the fake write mode based on a test mode operation signal.

14. The operating method of claim 13, wherein the test mode operation signal is a signal that a host transmits to a memory system.

15. The operating method of claim 13, wherein the test mode operation signal is a signal that a controller transmits to a test mode unit.

16. The operating method of claim 13, wherein the test mode operation signal is a signal that a host transmits to a memory system along with a write command.

17. The operating method of claim 13, wherein the performing of the fake write mode is carried out to request a controller to perform a fake write operation where a write operation is not actually performed on the memory device, and the controller performs the fake write operation.

18. The operating method of claim 13, wherein the performing of the fake write mode is carried out to request a controller to perform a fake write operation where a write operation is not actually performed on the memory device, and the controller performs a fake garbage collection operation in the fake write mode.

19. The operating method of claim 13, wherein the performing of the fake write mode is carried out to request a controller to perform a fake write operation where a write operation is not actually performed on the memory device, and the controller performs a fake erase operation in the fake write mode.

20. The operating method of claim 13, wherein the performing of the fake write mode is carried out to request a controller to perform a fake write operation where a write operation is not actually performed on the memory device, and the controller performs a map update operation in the fake write mode.
